(19) United States
(12) Patent Application Publication
(10) Pub. No.: US 2025/0386618 A1
(43) Pub. Date: Dec. 18, 2025

(54) LIGHT EMITTING ELEMENT, DISPLAY DEVICE INCLUDING THE LIGHT EMITTING ELEMENT, AND ELECTRONIC DEVICE INCLUDING THE DISPLAY DEVICE

(71) Applicant: Samsung Display Co., LTD., Yongin-si (KR)

(72) Inventors: Ju Yon LEE, Yongin-si (KR); Jong Moo HUH, Yongin-si (KR); Ji Wook MOON, Yongin-si (KR); Min Woo KIM, Yongin-si (KR); Chan Woo JOO, Yongin-si (KR)

(73) Assignee: Samsung Display Co., LTD., Yongin-si (KR)

(21) Appl. No.: 19/092,574

(22) Filed: Mar. 27, 2025

(30) Foreign Application Priority Data
Jun. 18, 2024 (KR) 10-2024-0078977
Aug. 30, 2024 (KR) 10-2024-0117617

(51) Int. Cl. H10H 20/831; H01L 25/075; H10H 20/813; H10H 20/832; H10H 20/855; H10H 20/857

(52) U.S. Cl. CPC H10H 20/831; H01L 25/0753; H10H 20/8131; H10H 20/835; H10H 20/855; H10H 20/857

(57) ABSTRACT

A light emitting element includes a light emitting stack, an auxiliary electrode covering a lower surface of the light emitting stack, a first insulation film covering an outer peripheral surface of the light emitting stack and the auxiliary electrode and including a first opening exposing a portion of a lower surface of the auxiliary electrode, a second insulation film covering an outer peripheral surface of the first insulation film, exposing an upper surface of the first insulation film, and including a second opening exposing the first opening, a first electrode electrically contacting the portion of the lower surface of the auxiliary electrode that is exposed by the first and second openings, and a second electrode embedded in the first insulation film and electrically contacting an upper surface of the light emitting stack.

### CROSS-REFERENCE TO RELATED APPLICATION(S)

This application claims priority to and benefits of Korean patent application 10-2024-0078977, filed on Jun. 18, 2024, and Korean patent application 10-2024-0117617, filed on Aug. 30, 2024, under 35 U.S.C. § 119(a), in the Korean Intellectual Property Office (KIPO), the entire contents of which are incorporated herein by reference.

### BACKGROUND

### 1. Technical Field

Embodiments of the disclosure relate to a light emitting element, a display device including the light emitting element, and an electronic device including the display device.

### 2. Description of the Related Art

A display device includes a pixel that includes a light emitting element. The light emitting elements are configured to be suitable for emitting light. The display device may display an image (or a video) by combining light emitted from the light emitting element included in the pixel.

Here, if luminous efficiency of the light emitting element is improved, the display quality of the display device may be improved.

### SUMMARY

An object of the disclosure is to provide a light emitting element with improved luminous efficiency.

Another object of the disclosure is to provide a display device including the light emitting element.

A light emitting element according to embodiments of the disclosure may include a light emitting stack including a first semiconductor layer, a second semiconductor layer disposed on the first semiconductor layer, and an active layer interposed between the first semiconductor layer and the second semiconductor layer, an auxiliary electrode covering a lower surface of the light emitting stack, a first insulation film covering an outer peripheral surface of the light emitting stack and the auxiliary electrode and including a first opening exposing a portion of a lower surface of the auxiliary electrode, a second insulation film covering an outer peripheral surface of the first insulation film, exposing an upper surface of the first insulation film, and including a second opening exposing the first opening and a portion of the first insulation film adjacent to the first opening, a first electrode electrically contacting the portion of the lower surface of the auxiliary electrode that is exposed by the first and second openings, and a second electrode embedded in the first insulation film and electrically contacting an upper surface of the light emitting stack. The second electrode may have a line or dotted line forming a closed-loop shape in a plan view.

In one embodiment, in a cross-sectional view, an upper surface of the second electrode and the upper surface of the first insulation film may be positioned at a same height.

In one embodiment, an area of the second opening may be greater than an area of the first opening in a plan view.

In one embodiment, the area of the second opening may be less than or equal to about 30% of an area of the lower surface of the light emitting stack in a plan view.

In one embodiment, in a plan view, the second electrode may overlap an edge of the first opening.

In one embodiment, the first electrode may include a reflective electrode electrically contacting the portion of the lower surface of the auxiliary electrode, and a bonding electrode disposed below the reflective electrode.

In one embodiment, a center of the closed-loop shape of the second electrode may overlap a center of the upper surface of the light emitting stack in a plan view.

In one embodiment, the second insulation film may have a laminated structure of a first insulation layer having a first refractive index, and a second insulation layer having a second refractive index that is different from the first refractive index.

In one embodiment, the second electrode may include a conductive metal oxide.

In one embodiment, in a cross-sectional view, the light emitting stack may have a trapezoidal shape in which a length of the upper surface is greater than a length of the lower surface.

A display device according to embodiments of the disclosure may include an anode electrode, a cathode electrode facing the anode electrode, and a light emitting element interposed between the anode electrode and the cathode electrode. The light emitting element may include a light emitting stack including a first semiconductor layer, a second semiconductor layer disposed on the first semiconductor layer, and an active layer interposed between the first semiconductor layer and the second semiconductor layer, an auxiliary electrode covering a lower surface of the light emitting stack, a first insulation film covering an outer peripheral surface of the light emitting stack and the auxiliary electrode and including a first opening exposing a portion of a lower surface of the auxiliary electrode, a second insulation film covering an outer peripheral surface of the first insulation film, exposing an upper surface of the first insulation film, and including a second opening exposing the first opening and a portion of the first insulation film adjacent to the first opening, a first electrode electrically contacting the portion of the lower surface of the auxiliary electrode that is exposed by the first and second openings and electrically connected to the anode electrode, and a second electrode embedded in the first insulation film, electrically contacting an upper surface of the light emitting stack, and electrically connected to the cathode electrode. The second electrode may have a line or dotted line forming a closed-loop shape in a plan view.

In one embodiment, in a cross-sectional view, an upper surface of the second electrode and the upper surface of the first insulation film may be positioned at a same height. The cathode electrode may electrically contact the upper surface of the second electrode.

In one embodiment, an area of the second opening may be greater than an area of the first opening in a plan view, and the area of the second opening may be less than or equal to about 30% of an area of the lower surface of the light emitting stack in a plan view.

In one embodiment, in a plan view, the second electrode may overlap an edge of the first opening.

In one embodiment, the first electrode may include a reflective electrode electrically contacting the portion of the lower surface of the auxiliary electrode, and a bonding electrode disposed below the reflective electrode and bonded to the anode electrode.

In one embodiment, a center of the closed-loop shape of the second electrode may overlap a center of the upper surface of the light emitting stack in a plan view.

In one embodiment, the second insulation film may have a laminated structure of a first insulation layer having a first refractive index, and a second insulation layer having a second refractive index that is different from the first refractive index.

In one embodiment, the second electrode may include a conductive metal oxide.

In one embodiment, in a cross-sectional view, the light emitting stack may have a trapezoidal shape in which a length of the upper surface is greater than a length of the lower surface.

An electronic device according to embodiments of the disclosure may include a processor that provides image data, and a display device that displays an image based on the image data. The display device may include an anode electrode, a cathode electrode facing the anode electrode, and a light emitting element interposed between the anode electrode and the cathode electrode. The light emitting element may include a light emitting stack including a first semiconductor layer, a second semiconductor layer disposed on the first semiconductor layer, and an active layer interposed between the first semiconductor layer and the second semiconductor layer, an auxiliary electrode covering a lower surface of the light emitting stack, a first insulation film covering an outer peripheral surface of the light emitting stack and the auxiliary electrode and including a first opening exposing a portion of a lower surface of the auxiliary electrode, a second insulation film covering an outer peripheral surface of the first insulation film, exposing an upper surface of the first insulation film, and including a second opening exposing the first opening and a portion of the first insulation film adjacent to the first opening, a first electrode electrically contacting a portion of the lower surface of the auxiliary electrode that is exposed by the first and second openings and electrically connected to the anode electrode, and a second electrode embedded in the first insulation film, electrically contacting an upper surface of the light emitting stack, and electrically connected to the cathode electrode. The second electrode may have a line or dotted line forming a closed-loop shape in a plan view.

According to an embodiment of the disclosure, the light emitting element may include a second electrode. The second electrode may play a role in centralizing a moving path of electrons in a second semiconductor layer. The light emitting element may include a first electrode, and the first electrode may electrically contact an auxiliary electrode in a first opening. The first electrode may play a role in centralizing a moving path of holes in a first semiconductor layer. As such, as the moving paths of electrons and holes are centralized, the luminous efficiency of the light emitting element may be improved.

A display device of the disclosure may include the light emitting element. Accordingly, the display quality of the display device may be improved.

### BRIEF DESCRIPTION OF THE DRAWINGS

FIG. 1 is a schematic block diagram for illustrating a display device according to embodiments of the disclosure.

FIG. 2 is a schematic block diagram for illustrating one of subpixels included in a display device of FIG. 1.

FIG. 3 is a plan view for illustrating a display panel constituting a display device of FIG. 1.

FIG. 4 is a schematic cross-sectional view illustrating one embodiment of a display panel of FIG. 3.

FIG. 5 is a schematic cross-sectional view illustrating another embodiment of a display panel of FIG. 3.

FIG. 6 to FIG. 8 are plan views for illustrating a light emitting element according to one embodiment of the disclosure.

FIG. 9 is a schematic cross-sectional view cut along line I1-I1′ of FIG. 6.

FIG. 10 is a plan view for illustrating a light emitting element according to another embodiment of the disclosure.

FIG. 11 is a plan view for illustrating one embodiment of one of pixels included in a display panel of FIG. 3.

FIG. 12 is a schematic cross-sectional view cut along line X-X′ of FIG. 11.

FIG. 13 is a schematic enlarged cross-sectional view of some of areas of FIG. 12.

FIG. 14 is a schematic block diagram for illustrating a display system according to one embodiment.

FIG. 15 to FIG. 18 are perspective views for illustrating embodiments of a display system of FIG. 14.

### DETAILED DESCRIPTION OF THE EMBODIMENTS

Hereinafter, embodiments will be described in detail with reference to the accompanying drawings. It should be noted that the following explanation describes only parts to understand the operation of the disclosure, and other parts of the description will be omitted not to obscure the gist of the disclosure. In addition, the disclosure is not limited to the embodiments described herein, but may be embodied in other forms. However, the embodiment described herein is provided to explain in such detail as to facilitate implementation of the technical idea of the disclosure to a person skilled in the art to which the disclosure pertains.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Terminology used herein is intended to describe specific embodiments and is not intended to limit the disclosure. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Herein, terms such as first and second may be used to describe various components, but these components are not limited to these terms. These terms are used to distinguish one component from another component. Accordingly, a first component may be referred to as a second component without departing from the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Various embodiments are described with reference to drawings illustrating ideal embodiments. Accordingly, it is to be expected, for example, that shapes may change depending on tolerances and/or manufacturing techniques. Thus, the embodiments disclosed herein may not be construed as being limited to the specific shapes depicted, but should be construed as including variations of the shapes resulting from, for example, manufacturing. As such, the shapes shown in the drawings may not show actual shapes of areas of the device, and the embodiments are not limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

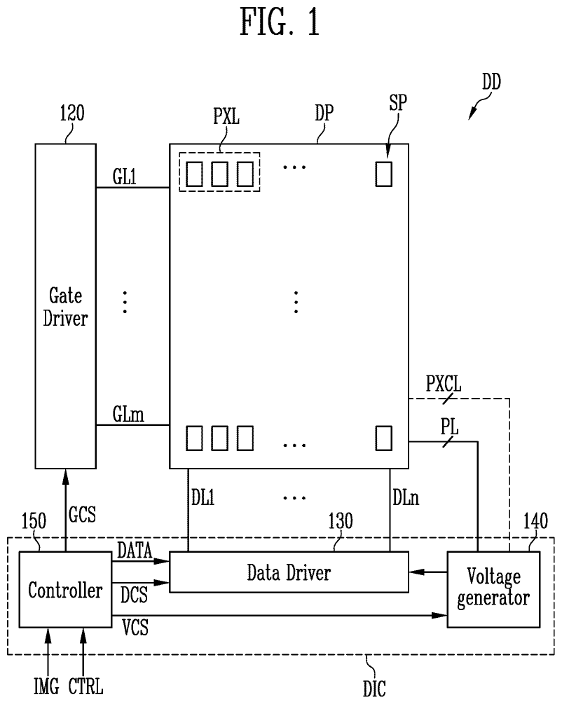

FIG. 1 is a schematic block diagram for illustrating a display device according to embodiments of the disclosure.

Referring to FIG. 1, a display device (DD) may include a display panel (DP), a gate driver 120, a data driver 130, a voltage generator 140, and a controller 150.

The display panel (DP) may include subpixels (SP). The subpixels (SP) may be connected to the gate driver 120 through first to m-th gate lines (GL1-GLm). The subpixels (SP) may be connected to the data driver 130 through first to n-th data lines (DL1-DLn).

The subpixels (SP) may generate light of two or more colors. For example, each of the subpixels (SP) may generate light such as red, green, blue, cyan, magenta, and yellow lights.

Two or more of the subpixels (SP) may constitute a single pixel (PXL). For example, the pixel (PXL) may include three subpixels, as shown in FIG. 1. As such, the pixel (PXL) may emit light of various colors and luminance depending on the combination of light emitted from the subpixels included in the pixel (PXL).

The gate driver 120 may be connected to the subpixels (SP) that are arranged in a row direction through the first to m-th gate lines (GL1-GLm). The gate driver 120 may output gate signals to the first to m-th gate lines (GL1-GLm) in response to gate control signals (GCS). In embodiments, the gate control signal (GCS) may include a start signal indicating the start of each frame, and a horizontal synchronization signal.

The gate driver 120 may be disposed on a side of the display panel (DP). However, embodiments are not limited thereto. For example, the gate driver 120 may be divided into two or more physically and/or logically distinct drivers, and such drivers may be disposed on a side of the display panel (DP) and on another side of the display panel (DP) that is opposed to the side. As such, the gate driver 120 may be disposed adjacent to the display panel (DP) in various forms according to embodiments.

The data driver 130 may be connected to the subpixels (SP) that are arranged in a column direction through the first to n-th data lines (DL1-DLn). The data driver 130 may receive image data (DATA) and data control signals (DCS) from the controller 150. The data driver 130 may operate in response to the data control signal (DCS). In embodiments, the data control signal (DCS) may include a source start signal, a source shift clock, and a source output enabling signal.

The data driver 130 may receive voltages from the voltage generator 140. The data driver 130 may apply, using the received voltages, data signals with gray scale voltages corresponding to the image data to the first to n-th data lines (DL1-DLn). In case that the gate signal is applied to each of the first to m-th gate lines (GL1-GLm), the data signals corresponding to the image data (DATA) may be applied to the data lines (DL1-DLn). Accordingly, the subpixels (SP) may generate light corresponding to the data signals, and the display panel (DP) may display images.

In embodiments, the gate driver 120 and the data driver 130 may include complementary metal-oxide semiconductor (CMOS) circuit elements.

The voltage generator 140 may operate in response to a voltage control signal (VCS) from the controller 150. The voltage generator 140 may be configured to generate multiple voltages and provide the generated voltages to components of the display device (DD) such as the gate driver 120, the data driver 130, and the controller 150. The voltage generator 140 may receive input voltages from the outside of the display device (DD) and regulate the received voltages to generate multiple voltages.

The voltage generator 140 may generate a first power supply voltage and a second power supply voltage. The first and second power supply voltages may be provided to the subpixels (SP) through power supply lines (PL). In other embodiments, at least one of the first and second power supply voltages may be provided from the outside of the display device (DD).

The voltage generator 140 may provide a variety of voltages and/or signals. For example, the voltage generator 140 may provide one or more initialization voltages that are applied to the subpixels (SP). For example, during a sensing operation to sense the electrical properties of transistors and/or light emitting elements of the subpixels (SP), a reference voltage may be applied to the first to n-th data lines (DL1-DLn), and the voltage generator 140 may generate the reference voltage to transmit to the data driver 130. For example, during a display operation to display an image on the display panel (DP), common pixel control signals may be applied to the subpixels (SP), and the voltage generator 140 may generate the pixel control signals. In embodiments, the voltage generator 140 may provide the pixel control signals to the subpixels (SP) through pixel control lines (PXCL). Shown in FIG. 1 is the pixel control lines (PXCL) that are connected between the voltage generator 140 and the display panel (DP), but the embodiments are not limited thereto. For example, the pixel control lines (PXCL) may be connected between the gate driver 120 and the display panel (DP), and the pixel control signals may be transmitted from the voltage generator 140 to the pixel control lines (PXCL) through the gate driver 120.

The controller 150 may control all the operations of the display device (DD). The controller 150 may receive, from the outside, input image data (IMG) and control signals (CTRL) corresponding to the input image data (IMG). The controller 150 may respond to the control signal (CTRL) to provide the gate control signal (GCS), the data control signal (DCS), and the voltage control signal (VCS).

The controller 150 may output the image data (DATA) by converting the input image data (IMG) to fit to the display device (DD) or the display panel (DP). In embodiments, the controller 150 may output image data (DATA) by aligning the input image data (IMG) to fit to the subpixels (SP) of a row unit.

Two or more components of the data driver 130, the voltage generator 140, and the controller 150 may be mounted in a single integrated circuit. As shown in FIG. 1, the data driver 130, the voltage generator 140, and the controller 150 may be included in a driver integrated circuit (DIC), and the data driver 130, the voltage generator 140, and the controller 150 may be functionally distinct components in a single driver integrated circuit (DIC). In other embodiments, at least one of the data driver 130, the voltage generator 140, and the controller 150 may be provided as a distinct component from the driver integrated circuit (DIC).

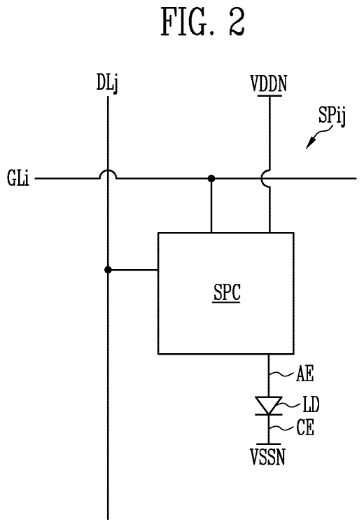

FIG. 2 is a schematic block diagram for illustrating one of subpixels included in a display device of FIG. 1. In FIG. 2, a subpixel (SPij) arranged in an i-th row (where i is greater than or equal to 1 and less than or equal to m) and a j-th column (where j is greater than or equal to 1 and less than or equal to n) of the subpixels (SP) of FIG. 1 is schematically illustrated.

Referring to FIG. 2, the subpixel (SPij) may include a subpixel circuit (SPC) and a light emitting element (LD).

The light emitting element (LD) may be connected between a first power supply voltage node (VDDN) and a second power supply voltage node (VSSN). The first power supply voltage node (VDDN) may be connected to one of the power supply lines (PL) of FIG. 1 and receive a first power supply voltage. The second power supply voltage node (VSSN) may be connected to another one of the power supply lines (PL) of FIG. 1 and receive a second power supply voltage. The first power supply voltage may have a higher voltage level than the second power supply voltage.

The light emitting element (LD) may be connected between an anode electrode (AE) and a cathode electrode (CE). The anode electrode (AE) may be connected to the first power supply voltage node (VDDN) through the subpixel circuit (SPC). For example, the anode electrode (AE) may be connected to the first power supply voltage node (VDDN) through one or more transistors included in the subpixel circuit (SPC). The cathode electrode (CE) may be connected to the second power supply voltage node (VSSN). The light emitting element (LD) may be configured to emit light according to the current flowing from the anode electrode (AE) to the cathode electrode (CE).

The subpixel circuit (SPC) may be connected to the i-th gate line (GLi) of the first to m-th gate lines (GL1-GLm) of FIG. 1, and the j-th data line (DLj) of the first to n-th data lines (DL1-DLn) of FIG. 1. In response to the gate signal received through the i-th gate line (GLi), the subpixel circuit (SPC) may control the light emitting element (LD) to emit light according to the data signal received through the j-th data line (DLj). In embodiments, the subpixel circuit (SPC) may be additionally connected to the pixel control lines (PXCL) of FIG. 1, and the subpixel circuit (SPC) may control the light emitting element (LD) by further responding to the pixel control signals received through the pixel control lines (PXCL).

For these operations, the subpixel circuit (SPC) may include circuit elements, such as transistors and one or more capacitors.

The transistors in the subpixel circuit (SPC) may be P-type transistors and/or N-type transistors. In embodiments, the transistors in the subpixel circuits (SPC) may be metal oxide silicon filed effect transistors (MOSFET). In embodiments, the transistors in the subpixel circuits (SPC) may include amorphous silicon semiconductors, monocrystalline silicon semiconductors, polycrystalline silicon semiconductors, and/or oxide semiconductors.

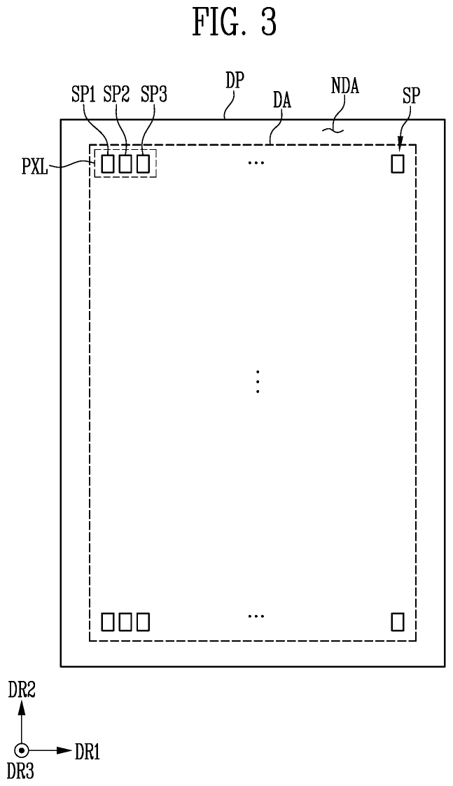

FIG. 3 is a plan view for illustrating a display panel constituting the display device of FIG. 1.

Referring to FIG. 3, the display panel (DP) may include a display area (DA) and a non-display area (NDA). The display panel (DP) may display images through the display area (DA). The non-display area (NDA) may be disposed adjacent to the display area (DA).

The display panel (DP) may include the subpixels (SP) in the display area (DA). The subpixels (SP) may be arranged in a first direction (DR1) and a second direction (DR2) intersecting the first direction (DR1). For example, the subpixels (SP) may be arranged in a matrix form in the first direction (DR1) and the second direction (DR2). In another embodiment, the subpixels (SP) may be arranged in a zigzag form in the first direction (DR1) and the second direction (DR2). The arrangement of the subpixels (SP) may vary according to embodiments. The first direction (DR1) may be a row direction, and the second direction (DR2) may be a column direction.

Two or more of the subpixels (SP) may constitute a single pixel (PXL). FIG. 3 shows that the pixel (PXL) includes three subpixels (SP1, SP2, SP3), but the embodiments are not limited thereto. For example, the pixel (PXL) may include two subpixels. Hereinafter, for convenience of explanation, an embodiment that the pixel (PXL) includes the first to third subpixels (SP1, SP2, SP3) will be described.

Each of the first to third subpixels (SP1, SP2, SP3) may generate light of one of various colors, such as red, green, blue, cyan, magenta, and yellow. Hereinafter, for clear and concise explanation, an embodiment that the first subpixel (SP1) is configured to generate red light, the second subpixel (SP2) is configured to generate green light, and the third subpixel (SP3) is configured to generate blue light will be described.

Each of the first to third subpixels (SP1, SP2, SP3) may include at least one light emitting element configured to generate light. In embodiments, the light emitting elements of the first to third subpixels (SP1, SP2, SP3) may generate light of a same color. For example, the light emitting elements of the first to third subpixels (SP1, SP2, SP3) may generate blue light. In other embodiments, the light emitting elements of the first to third subpixels (SP1, SP2, SP3) may generate light of different colors. For example, the light emitting elements of the first to third subpixels (SP1, SP2, SP3) may generate red, green, and blue light, respectively.

As a display panel (DP), the display panel capable of self-emitting light may be used, such as a light emitting diode (LED) display panel that uses a microscale or nanoscale light emitting diode as a light emitting element, or an organic light emitting display (OLED) panel that uses an organic light emitting diode as a light emitting element.

In the non-display area (NDA), a component for controlling the subpixels (SP) may be disposed. Wiring connected with subpixels (SP), e.g., the first to m-th gate lines (GL1-GLm), the first to n-th data lines (DL1-DLn), the power supply lines (PL), and the pixel control lines (PXCL) of FIG. 1 may be disposed in the non-display area (NDA).

At least one of the gate driver 120, the data driver 130, the voltage generator 140, and the controller 150 of FIG. 1 may be disposed in the non-display area (NDA) of the display panel (DP). In embodiments, the gate driver 120 may be disposed in the non-display area (NDA), the data driver 130, the voltage generator 140, and the controller 150 may be implemented as the driver integrated circuit (DIC) of FIG. 1 distinct from the display panel (DP), and the driver integrated circuit (DIC) may be connected to wiring disposed in the non-display area (NDA). In other embodiments, the gate driver 120 may be implemented as a single integrated circuit distinct from the display panel (DP) along with the data driver 130, the voltage generator 140, and the controller 150.

In embodiments, the display area (DA) may have a variety of shapes. The display area (DA) may have a closed-loop shape that includes straight and/or curved sides in a plan view. For example, the display area (DA) may have shapes such as polygons, circles, semicircles, and ellipses.

In embodiments, the display panel (DP) may have a flat display surface. In other embodiments, the display panel (DP) may have a display surface that is rounded at least partially.

In embodiments, the display panel (DP) may be bendable, foldable, or rollable, and the display panel (DP) and/or a substrate of the display panel (DP) may include a material having flexibility.

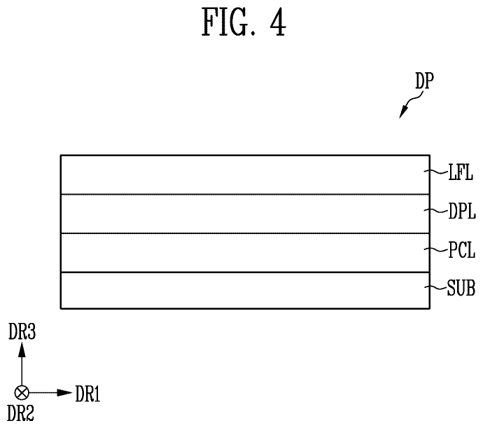

FIG. 4 is a schematic cross-sectional view illustrating one embodiment of the display panel of FIG. 3.

Referring to FIG. 4, the display panel (DP) may include a substrate (SUB) and a pixel circuit layer (PCL), a display element layer (DPL), and a light functional layer (LFL) that are sequentially laminated on the substrate in a third direction (DR3) intersecting the first and second directions (DR1, DR2).

The substrate (SUB) may be made up of an insulating material such as glass and a resin. For example, the substrate (SUB) may include a glass substrate. In another embodiment, the substrate (SUB) may include a polyimide (PI) substrate. In another embodiment, the substrate (SUB) may include a silicon wafer substrate formed using a semiconductor process.

In embodiments, the substrate (SUB) may consist of a flexible material that allows for bending or folding and have a single-layer or multi-layer structure. For example, the substrate (SUB) may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer (PCL) may be disposed on the substrate (SUB). The pixel circuit layer (PCL) may include insulation layers as well as semiconductor patterns and conductive patterns disposed between the insulation layers. The conductive patterns of the pixel circuit layer (PCL) may function as circuit elements and wiring.

The circuit elements of the pixel circuit layer (PCL) may include the subpixel circuit (SPC, see FIG. 2) for each of the subpixels (SP) of FIG. 3. In other words, the circuit elements in the pixel circuit layer (PCL) may be provided with transistors of the subpixel circuit (SPC) and one or more capacitors.

The wiring of the pixel circuit layer (PCL) may include wiring connected to the subpixels (SP). The wiring of the pixel circuit layer (PCL) may include the various signal lines and/or voltage lines required to drive the display element layer (DPL).

The display element layer (DPL) may be disposed on the pixel circuit layer (PCL). The display element layer (DPL) may include light emitting elements of the subpixels (SP).

The light functional layer (LFL) may be disposed on the display element layer (DPL). The light functional layer (LFL) may include light conversion patterns with light conversion particles and/or scattering particles. For example, the light conversion particles may include quantum dots. The quantum dots may change the wavelength (or color) of light emitted from the display element layer (DPL). The light functional layer (LFL) may further include light scattering patterns having scattering particles. In embodiments, light conversion patterns and light scattering patterns may be omitted.

The light functional layer (LFL) may further include color filter layers that include color filters. The color filter may selectively transmit light of a specific wavelength (or a specific color). In embodiments, the color filter layer may be omitted.

Although not illustrated, a window may be provided to protect the exposed surface (or an upper surface) of the display panel (DP) on the light functional layer (LFL). The window may protect the display panel (DP) from external shocks. The window may be bonded to the light functional layer (LFL) by an optical transparent adhesive (or cohesive) member. The window may have a multi-layer structure including a glass substrate, a plastic film, or a plastic substrate. These multi-layered structure may be formed through a continuous process or an adhesive process using an adhesive layer. All or part of the window may have flexibility.

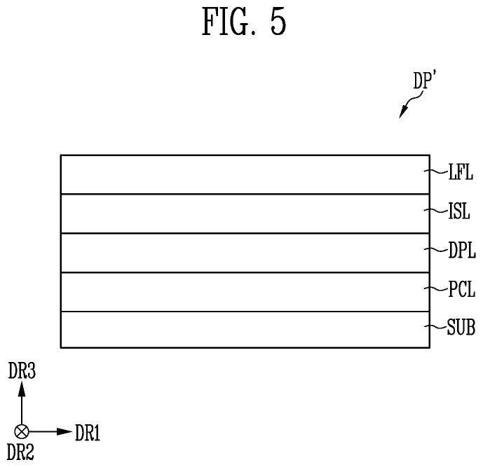

FIG. 5 is a schematic cross-sectional view illustrating another embodiment of the display panel of FIG. 3.

Referring to FIG. 5, a display panel (DP′) may include the substrate (SUB), the pixel circuit layer (PCL), the display element layer (DPL), an input sensing layer (ISL), and the light functional layer (LFL). The substrate (SUB), the pixel circuit layer (PCL), the display element layer (DPL), and the light functional layer (LFL) may be configured to be similar to the substrate (SUB), the pixel circuit layer (PCL), the display element layer (DPL), and the light functional layer (LFL) described in reference to FIG. 4. Hereinafter, duplicate explanations are omitted.

The input sensing layer (ISL) may sense user input to the upper surface (or a display surface) of the display panel (DP′). The input sensing layer (ISL) may include configurations suitable for sensing external objects such as the user's hand and pen. For example, the input sensing layer (ISL) may include touch electrodes.

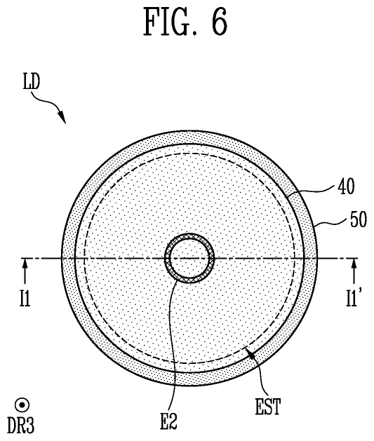

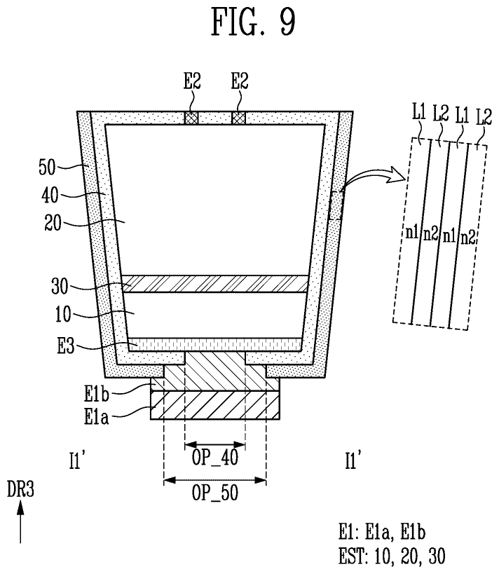

FIG. 6 to FIG. 8 are plan views for illustrating a light emitting element according to one embodiment of the disclosure. FIG. 9 is a schematic cross-sectional view cut along line I1-I1′ of FIG. 6.

Referring to FIG. 6 to FIG. 9, the light emitting element (LD) may include a light emitting stack (EST), an auxiliary electrode (E3), a first insulation film 40, a second insulation film 50, a first electrode (E1), and a second electrode (E2). The light emitting stack (EST) may include a first semiconductor layer 10, a second semiconductor layer 20, and an active layer 30. The light emitting element (LD) may be implemented as a vertical light emitting element in which the first electrode (E1), the auxiliary electrode (E3), the first semiconductor layer 10, the active layer 30, the second semiconductor layer 20, and the second electrode (E2) are sequentially stacked in the third direction (DR3).

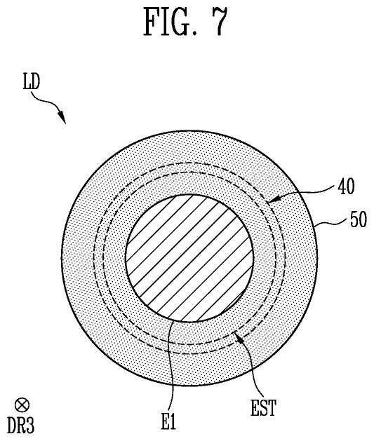

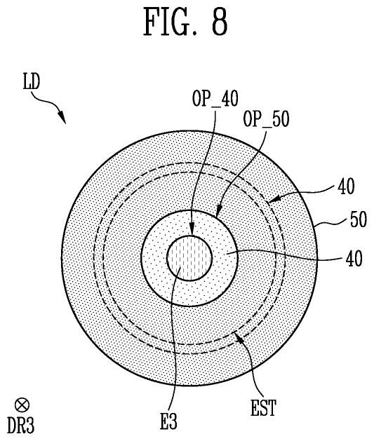

In FIG. 6, the upper surface of the light emitting element (LD) is shown, and in FIG. 7 and FIG. 8, the lower surface of the light emitting element (LD) is shown. In FIG. 8, the first electrode (E1) is omitted.

The first semiconductor layer 10 may be configured to provide holes. The first semiconductor layer 10 may have a first polarity. For example, the first semiconductor layer 10 may include at least one P-type semiconductor layer. For example, the first semiconductor layer 10 may include at least one of gallium nitride (GaN), aluminum gallium nitride (AlGaN), indium gallium nitride (InGaN), aluminum nitride (AlN), and indium nitride (InN), and may be a P-type semiconductor layer doped with a first conductive dopant (or a P-type dopant) such as magnesium (Mg), zinc (Zn), calcium (Ca), strontium (Sr), and barium (Ba). However, the materials constituting the first semiconductor layer 10 are not limited thereto, and various other materials may make up the first semiconductor layer 10. In one embodiment, the first semiconductor layer 10 may include a gallium nitride (GaN) doped with the first conductive dopant (or a P-type dopant).

The second semiconductor layer 20 may be disposed on the first semiconductor layer 10. The second semiconductor layer 20 may be configured to provide electrons. The second semiconductor layer 20 may have a second polarity that is different from the first polarity. For example, the second semiconductor layer 20 may include at least one N-type semiconductor layer. For example, the second semiconductor layer 20 may include at least one of gallium nitride (GaN), aluminum gallium nitride (AlGaN), indium gallium nitride (InGaN), aluminum nitride (AlN), and indium nitride (InN), and may be an N-type semiconductor layer doped with a second conductive dopant (or an N-type dopant) such as silicon (Si), germanium (Ge), and tin (Sn). However, the materials constituting the second semiconductor layer 20 are not limited thereto, and various other materials may make up the second semiconductor layer 20. In one embodiment, the second semiconductor layer 20 may include a gallium nitride (GaN) doped with the second conductive dopant (or an N-type dopant).

The active layer 30 may be interposed between the first semiconductor layer 10 and the second semiconductor layer 20. The active layer 30 may provide an area where electrons and holes recombine. As the electrons and holes recombine in the active layer 30, transition to a lower energy level may occur to cause generation of light with a wavelength corresponding to the energy transition. The active layer 30 may have a single- or multi-quantum well structure. If the active layer 30 is formed as a multi-quantum well structure, units including a barrier layer, a strain reinforcing layer, and a well layer may be repeatedly stacked each other to form the active layer 30. However, the active layer 30 is not limited to the aforementioned structure.

In one embodiment, as shown in FIG. 9, in a cross-sectional view, the light emitting stack (EST) may have a trapezoidal shape in which a length of the upper side is longer than a length of the lower side, and the light extraction efficiency by the second insulation film 50 that covers the outer peripheral surface of the light emitting stack (EST) may be further improved.

The auxiliary electrode (E3) may cover the lower surface of the light emitting stack (EST). In other words, the auxiliary electrode (E3) may cover the lower surface of the first semiconductor layer 10. The auxiliary electrode (E3) may include a conductive metal oxide. For example, the auxiliary electrode (E3) may include indium tin oxide (ITO). However, the materials constituting the auxiliary electrode (E3) are not limited thereto, and the auxiliary electrode (E3) may be composed of another conductive material.

The first insulation film 40 may cover the outer peripheral surface of the light emitting stack (EST) and the auxiliary electrode (E3). The first insulation film 40 may include a first opening (OP_40) exposing a portion of the lower surface of the auxiliary electrode (E3). The first insulation film 40 may include a transparent insulating material. The first insulation film 40 may play a role in preventing electrical short circuits that may occur in case that the active layer 30 comes in contact with other conductive materials other than the first and second semiconductor layers 10 and 20.

The second insulation film 50 may cover the outer periphery surface of the first insulation film 40 and expose the upper surface of the first insulation film 40. The second insulation film 50 may include a second opening (OP_50) exposing the first opening (OP_40) and the first insulation film 40 adjacent to the first opening (OP_40).

In one embodiment, the second insulation film 50 may have a laminated structure of a first insulation layer (L1) having a first refractive index (n1) and a second insulation layer (L2) having a second refractive index (n2) different from the first refractive index (n1). Due to the difference in the refractive index of the first insulation layer (L1) and the second insulation layer (L2), the light emitted from the active layer 30 may be guided in a direction of light emission (e.g., in a direction toward the upper surface of the light emitting stack (EST)). Thus, the light emission efficiency of the light emitting element (LD) may be improved.

The first electrode (E1) may electrically contact a portion of the lower surface of the auxiliary electrode (E3) that is exposed by the first and second openings (OP_40, OP_50). The first electrode (E1) may include a conductive material.

In one embodiment, the first electrode (E1) may include a reflective electrode (E1b) and a bonding electrode (E1a).

The reflective electrode (E1b) may be in electrical contact with a portion of the lower surface of the auxiliary electrode (E3). The reflective electrode (E1b) may consist of a conductive material with a reflectivity. For example, the reflective electrode (E1b) may include an opaque metal. For example, the reflective electrode (E1b) may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, the material of the reflective electrode (E1b) is not limited thereto. By means of the reflective electrode (E1b), the light emission efficiency of the light emitting element (LD) may be improved.

The bonding electrode (E1a) may be disposed below the reflective electrode (E1b). The bonding electrode (E1b) may include a eutectic metal.

The second electrode (E2) may be disposed on the light emitting stack (EST). The second electrode (E2) may be embedded in the first insulation film 40 that covers the upper surface of the light emitting stack (EST). The second electrode (E2) may electrically contact the upper surface of the light emitting stack (EST). In other words, the second electrode (E2) may electrically contact the upper surface of the second semiconductor layer 20. As shown in FIG. 9, in a cross-sectional view, the upper surface of the second electrode (E2) and the upper surface of the first insulation film 40 may be positioned at a same height.

The second electrode (E2) may have a line forming a closed-loop shape in a plan view. For example, the second electrode (E2), as shown in FIG. 6, may have a doughnut shape in a plan view. However, the planar shape of the second electrode (E2) is not limited thereto. The second electrode (E2) may have an oval, polygonal, or closed-loop shape consisting of one or more straight lines and/or one or more curved lines in a plan view.

In response to the electrical signal provided through the second electrode (E2), a moving path of electrons may be formed in the second semiconductor layer 20 in a direction from the second electrode (E2) toward the active layer 30. The moving path of electrons in the second semiconductor layer 20 may generally be formed in the shortest path from the second electrode (E2) toward the active layer 30. As the second electrode (E2) is configured as described above, the moving path of electrons in the second semiconductor layer 20 may be more centralized. Accordingly, electrons moving in the second semiconductor layer 20 may not be provided to a side of the second semiconductor layer 20 with relatively many defects, and electrons may be provided to the active layer 30 more efficiently.

Similarly, in response to the electrical signal provided through the first electrode (E1), a moving path of holes may be formed in the first semiconductor layer 10 in a direction from the first electrode (E1) toward the active layer 30. The moving path of holes in the first semiconductor layer 10 may generally be formed as the shortest path from a contact surface of the first electrode (E1) that is in electrical contact with the auxiliary electrode (E3) in the first opening (OP_40) toward the active layer 30. As the first electrode (E1) is configured as described above, the moving path of holes in the first semiconductor layer 10 may be more centralized. Accordingly, the holes moving in the first semiconductor layer 10 may not be provided to a side of the first semiconductor layer 10 with relatively many defects, and the holes may be provided to the active layer 30 more efficiently.

In one embodiment, as shown in FIG. 8, an area (or size) of the second opening (OP_50) may be greater than an area (or size) of the first opening (OP_40) in a plan view. The area of the second opening (OP_50) may be approximately less than or equal to about 30% of the area of the lower surface of the light emitting stack (EST) in a plan view. If the area of the first opening (OP_40) and the area of the second opening (OP_50) satisfy the aforementioned descriptions, the moving path of holes in the first semiconductor layer 10 may be centralized more effectively.

In one embodiment, as shown in FIG. 6, FIG. 8, and FIG. 9, in a plan view, the second electrode (E2) may overlap an edge of the first opening (OP_40), and the moving path of electrons in the second semiconductor layer 20 and the moving path of holes in the first semiconductor layer 10 may be aligned (or overlap), such that the electron and the hole may be combined in the active layer 30 more efficiently.

In one embodiment, the center of the closed-loop shape defined by the second electrode (E2) may overlap the center of the upper surface of the light emitting stack (EST) in a plan view, and a sufficient separation distance may be secured between the moving path of electrons in the second semiconductor layer 20 and the side of the second semiconductor layer 20. Thus, electrons moving in the second semiconductor layer 20 may not be provided to the side of the second semiconductor layer 20 with relatively many defects.

In one embodiment, the second electrode (E2) may be configured to be substantially transparent or semi-transparent to satisfy a light transmission. For example, the second electrode (E2) may include a conductive metal oxide. For example, the second electrode (E2) may include a transparent conductive material including at least one of indium tin oxide (ITO), indium zinc oxide (IZO), zinc oxide (ZnO), indium gallium zinc oxide (IGZO), and indium tin zinc oxide (ITZO). Accordingly, even if the second electrode (E2) is disposed on a light emitting surface (i.e., an upper surface) of the light emitting stack (EST), the light emission efficiency of the light emitting element (LD) may not be substantially reduced.

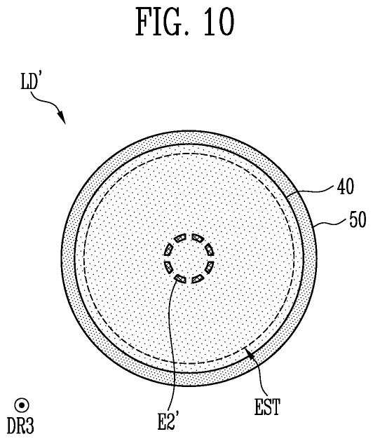

FIG. 10 is a plan view for illustrating a light emitting element according to another embodiment of the disclosure.

Referring to FIG. 10, the upper surface of a light emitting element (LD′) according to the embodiment is shown. Hereinafter, in describing the light emitting element (LD′), the description will be set forth on the differences from the light emitting element (LD) described in reference to FIG. 6 to FIG. 9, and the omitted description is redisposed with those mentioned above.

The light emitting element (LD′) may include a second electrode (E2′). The light emitting element (LD′) may be configured to be substantially identical to the light emitting element (LD) described in reference to FIG. 6 to FIG. 9, except for the planar shape of the second electrode (E2′). The second electrode (E2′) may have a dotted forming a closed-loop shape in a plan view. Compare to the light emitting element (LD) including the second electrode (E2) described in reference to FIG. 6 to FIG. 9, the light emission efficiency of the light emitting element (LD′) including the second electrode (E2′) may further be improved

Hereinafter, description will be set forth on the basis of the display device including the light emitting element (LD) described in reference to FIG. 6 to FIG. 9. The following content may be applied to be substantially identical (or similar) to the light emitting element (LD′) described in reference to FIG. 10.

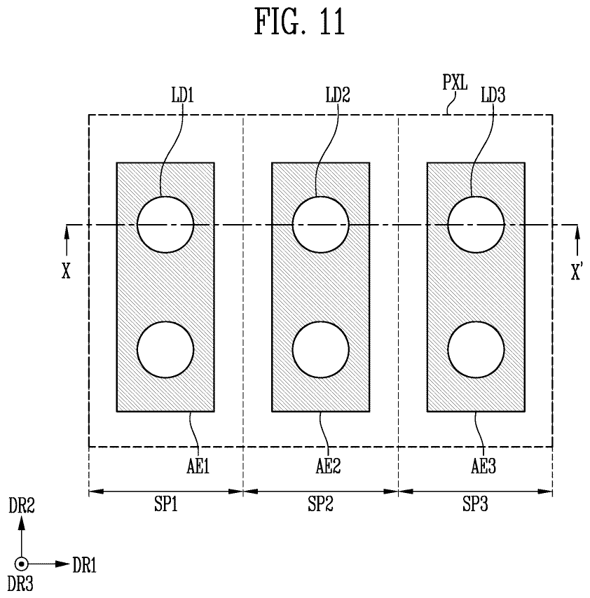

FIG. 11 is a plan view for illustrating one embodiment of one of pixels included in the display panel of FIG. 3.

Referring to FIG. 11, the pixels (PXL) may include the first to third subpixels (SP1, SP2, SP3). The first to third subpixels (SP1, SP2, SP3) may be arranged in the first direction (DR1). However, the arrangement of subpixels (SP1, SP2, SP3) is not limited thereto and may vary depending on the embodiments. For example, the first to third subpixels (SP1, SP2, SP3) may be arranged in a zigzag.

First to third anode electrodes (AE1, AE2, AE3) may each be disposed in the first to third subpixels (SP1, SP2, SP3). The first anode electrode (AE1) may be provided as the anode electrode (AE) included in the subpixel circuit (SPC, see FIG. 2) of the first subpixel (SP1). The second anode electrode (AE2) may be provided as the anode electrode (AE) included in the subpixel circuit (SPC, see FIG. 2) of the second subpixel (SP2). The third anode electrode (AE3) may be provided as the anode electrode (AE) included in the subpixel circuit (SPC, see FIG. 2) of the third subpixel (SP3).

One or more first light emitting elements (LD1), one or more second light emitting elements (LD2), and one or more third light emitting elements (LD3) may be disposed on the first to third anode electrodes (AE1, AE2, AE3). The first light emitting elements (LD1) may be connected to the first anode electrode (AE1). The second light emitting elements (LD2) may be connected to the second anode electrode (AE2). The third light emitting elements (LD3) may be connected to the third anode electrode (AE3). If multiple light emitting elements are provided in each subpixel, each anode electrode may have a shape that extends in a direction such as the second direction (DR2), and the light emitting elements connected to the anode electrodes may be arranged in a same direction.

The first light emitting elements (LD1) may be provided as a light emitting element (LD, see FIG. 2 and FIG. 6 to FIG. 9) included in the first subpixel (SP1). The second light emitting elements (LD2) may be provided as the light emitting element (LD, see FIG. 2 and FIG. 6 to FIG. 9) included in the second subpixel (SP2). The third light emitting elements (LD3) may be provided as the light emitting element (LD, see FIG. 2 and FIG. 6 to FIG. 9) included in the third subpixel SP3. If multiple light emitting elements are provided in one subpixel, the light emitting elements may be provided as a light emitting element (LD) of FIG. 2 by being connected in parallel between the anode electrode and the cathode electrode.

Each of the first light emitting elements (LD1), the second light emitting elements (LD2), and the third light emitting elements (LD3) may be configured to be substantially identical to one of the light emitting elements (LD, LD′) described in reference to FIG. 6 to FIG. 10.

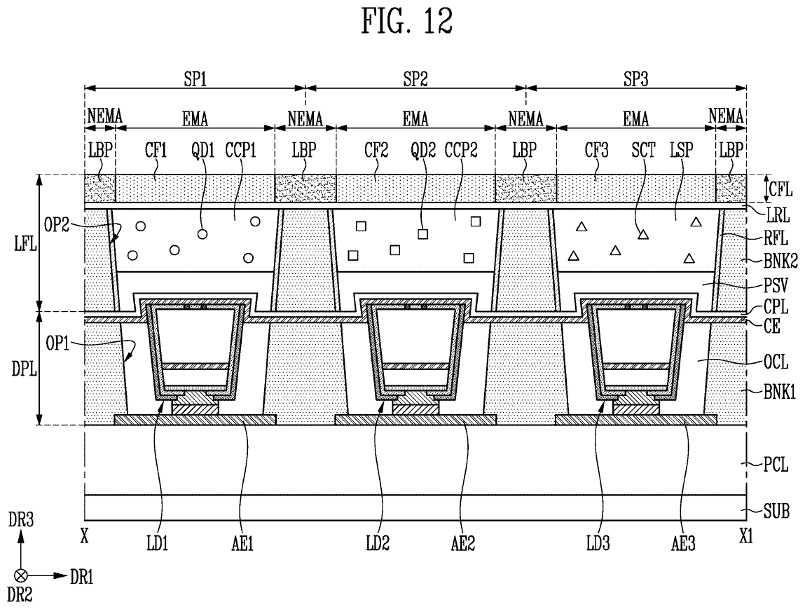

FIG. 12 is a schematic cross-sectional view cut along line X-X′ of FIG. 11.

Referring to FIG. 11 and FIG. 12, the pixel circuit layer (PCL), the display element layer (DPL), and the light functional layer (LFL) may be sequentially disposed on the substrate (SUB).

The pixel circuit layer (PCL) may include insulation layers, semiconductor patterns, and conductive patterns laminated on the substrate (SUB). The semiconductor patterns and the conductive patterns may be positioned between the insulation layers. These semiconductor patterns and conductive patterns may constitute circuit elements (e.g., transistors, one or more capacitors, and wiring), and the circuit elements may constitute subpixel circuits (SPC) for each of the first to third subpixels (SP1, SP2, SP3).

On the pixel circuit layer (PCL), the first to third anode electrodes (AE1, AE2, AE3) may be disposed in the first to third subpixels (SP1, SP2, SP3), respectively.

The first anode electrode (AE1) may be electrically connected to one subpixel circuit (SPC) in the pixel circuit layer (PCL). The second anode electrode (AE2) may be electrically connected to another subpixel circuit (SPC) of the pixel circuit layer (PCL). The third anode electrode (AE3) may be electrically connected to another subpixel circuit (SPC) of the pixel circuit layer (PCL).

A first bank (BNK1) may be disposed on the first to third anode electrodes (AE1, AE2, AE3). The first bank (BNK1) may have first openings (OP1) exposing a portion of each of the first to third anode electrodes (AE1, AE2, AE3). The first to third light emitting elements (LD1, LD2, LD3) may be disposed in the first openings (OP1) of the first bank (BNK1). The first bank (BNK1) may function as a pixel defining film that defines areas where the first to third light emitting elements (LD1, LD2, LD3) are positioned.

The first bank (BNK1) may include a light blocking material to play a role in preventing light mixing among neighboring subpixels. In embodiments, the first bank (BNK1) may include an organic material. For example, the first bank (BNK1) may include an organic insulating material such as an acrylic resin, an epoxy resin, a phenol resin, a polyamide resin, and a polyimide resin. In embodiments, in order to further improve the light emission efficiency, a reflective layer including a reflective material may be further disposed on the side of the first bank (BNK1) adjacent to the first openings (OP1).

The first to third light emitting elements (LD1, LD2, LD3) may be disposed on the first to third anode electrodes (AE1, AE2, AE3), respectively. The first to third light emitting elements (LD1, LD2, LD3) may be bonded and coupled to the first to third anode electrodes (AE1, AE2, AE3), respectively.

The bonding electrode (E1a, see FIG. 9) of the first light emitting element (LD1) may be bonded and coupled to the first anode electrode (AE1). The bonding electrode (E1a, see FIG. 9) of the second light emitting element (LD2) may be bonded and coupled to the second anode electrode (AE2). The bonding electrode (E1a, see FIG. 9) of the third light emitting element (LD3) may be bonded and coupled to the third anode electrode (AE3).

The second electrode (E2, see FIG. 9) of the first light emitting element (LD1) may be connected to the cathode electrode (CE). The second electrode (E2, see FIG. 9) of the second light emitting element (LD2) may be connected to the cathode electrode (CE). The second electrode (E2, see FIG. 9) of the third light emitting element (LD3) may be connected to the cathode electrode (CE).

Accordingly, the first to third light emitting elements (LD1, LD2, LD3) may be connected between the first to third anode electrodes (AE1, AE2, AE3) and the cathode electrode (CE).

An overcoat layer (OCL) may be disposed in the first openings (OP1) in which the first to third light emitting elements (LD1, LD2, LD3) are disposed. The overcoat layer (OCL) may play a role in immobilizing the first to third light emitting elements (LD1, LD2, LD3) bonded to the first to third anode electrodes (AE1, AE2, AE3). The overcoat layer (OCL) may protect the components disposed below the overcoat layer (OCL) from foreign substances such as dust and moisture. The overcoat layer (OCL) may include at least one of an inorganic insulating layer and an organic insulation layer. For example, the overcoat layer (OCL) may include epoxy, but the embodiments are not limited thereto.

In embodiments, the overcoat layer (OCL) may not be disposed on the upper surface of the first to third light emitting elements (LD1, LD2, LD3). The first to third light emitting elements (LD1, LD2, LD3) may protrude toward the light functional layer (LFL). The first to third light emitting elements (LD1, LD2, LD3) may be positioned at least partially in the second openings (OP2) of a second bank (BNK2). For example, the height of the upper surface of each of the first to third light emitting elements (LD1, LD2, LD3) from the substrate (SUB) may be greater than the bottommost end of the reflective layer (RFL). Accordingly, light emitted from the first to third light emitting elements (LD1, LD2, LD3) may be provided to the light functional layer (LFL) at a relatively high rate.

The cathode electrode (CE) may be disposed on the first to third light emitting elements (LD1, LD2, LD3). The cathode electrode (CE) may be disposed as a whole over the first bank (BNK1), the first to third light emitting elements (LD1, LD2, LD3), and the overcoat layer (OCL). The cathode electrode (CE) may be in electrical contact with the second electrodes (E2, see FIG. 9) of each of the first to third light emitting elements (LD1, LD2, LD3). The cathode electrode (CE) may be electrically connected to the second power supply voltage node (VSSN) in FIG. 2. The second power supply voltage, that is applied to the second power supply voltage node (VSSN), may be transmitted to the first to third light emitting elements (LD1, LD2, LD3) through the cathode electrode (CE).

The cathode electrode (CE) may be substantially transparent or semi-transparent to satisfy a light transmission. In embodiments, the cathode electrode (CE) may include a transparent conductive material including at least one of indium tin oxide (ITO), indium zinc oxide (IZO), zinc oxide (ZnO), indium gallium zinc oxide (IGZO), and indium tin zinc oxide (ITZO). However, the material of the cathode electrode (CE) is not limited thereto.

A capping layer (CPL) may be disposed on the cathode electrode (CE). The capping layer (CPL) may protect components below the capping layer (CPL), such as the cathode electrode (CE) and the first to third light emitting elements (LD1, LD2, LD3), from external water and moisture. The capping layer (CPL) may include a metal oxide such as silicon nitride, silicon oxide, silicon oxynitride, and aluminum oxide. However, the material of the capping layer (CPL) is not limited thereto.

The light functional layer (LFL) may be disposed on the capping layer (CPL). The light functional layer (LFL) may include the second bank (BNK2), the reflective layer (RFL), a passivation layer (PSV), first and second light conversion patterns (CCP1, CCP2), a light scattering pattern (LSP), a low refractive layer (LRL), and a color filter layer (CFL).

The second bank (BNK2) may be disposed on the capping layer (CPL). The second bank (BNK2) may overlap the first bank (BNK1) in the third direction DR3. The second bank (BNK2) may have the second openings (OP2) that overlap the first openings (OP1) in the third direction DR3.

The second bank (BNK2) may include a light blocking material to prevent light mixing between neighboring pixels and the first to third subpixels (SP1, SP2, SP3). In embodiments, the second bank (BNK2) may include an organic material. For example, the second bank (BNK2) may include an organic insulating material such as an acryl resin, an epoxy resin, a phenol resin, a polyamide resin, and a polyimide resin.

On the sides of the second bank (BNK2) adjacent to the second openings (OP2), the reflective layer (RFL) may be disposed. The reflective layer (RFL) may reflect the incident light, thereby improving the light emission efficiency. The reflective layer (RFL) may include a material suitable for reflecting light. The reflective layer (RFL) may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy thereof. However, embodiments are not limited thereto.

that the second bank (BNK2) may define a light emitting area (EMA) and a non-light emitting area (NEMA) for the first to third subpixels (SP1, SP2, SP3). An area that overlaps the second bank (BNK2) in the third direction DR3 may correspond to the non-light emitting area (NEMA). An area that overlaps the second openings (OP2) of the second bank (BNK2) in the third direction DR3 may correspond to the light emitting area (EMA).

On the capping layer (CPL), a passivation layer (PSV) may be disposed in the second openings (OP2). The passivation layer (PSV) may protect the components disposed below the passivation layer (PSV) and provide a flat upper surface. The passivation layer (PSV) may include an inorganic insulating material and/or an organic insulating material.

On the passivation layer (PSV), the first and second light conversion patterns (CCP1, CCP2) and the light scattering patterns (LSP) may be disposed in the second openings (OP2).

The first and second light conversion patterns (CCP1, CCP2) and the light scattering pattern (LSP) may include light conversion particles and/or scattering particles. The light conversion particles may convert incident light into light of a different color by changing the wavelength of the incident light. The light conversion particles may scatter incident light. In embodiments, the light conversion particles may be quantum dots. The scattering particles may scatter incident light.

In embodiments, the first to third light emitting elements (LD1, LD2, LD3) may be configured to emit blue light. The first light conversion pattern (CCP1) may include first color conversion particles (QD1) that are configured to convert blue light into red light. The second light conversion pattern (CCP2) may include second color conversion particles (QD2) that are configured to convert blue light into green light. The light scattering pattern (LSP) may include scattering particles (SCT) that scatter blue light to improve light emission efficiency. Accordingly, the first to third subpixels (SP1, SP2, SP3) may be provided as red subpixels, green subpixels, and blue subpixels, respectively. In embodiments, at least one of the first and second light conversion patterns (CCP1, CCP2) and the light scattering pattern (LSP) may further include light conversion particles that convert blue light into white light.

In embodiments, the first to third light emitting elements (LD1, LD2, LD3) may be configured to emit red, green, and blue light, respectively, and the first and second light conversion patterns (CCP1, CCP2) and the light scattering pattern (LSP) may each include scattering particles (SCT). As such, the particles included in the first and second light conversion patterns (CCP1, CCP2) and the light scattering patterns (LSP) may vary depending on the color of the light emitted by the first to third light emitting elements (LD1, LD2, LD3).

In embodiments, the first and second light conversion patterns (CCP1, CCP2) and the light scattering patterns (LSP) may be omitted.

A low refractive layer (LRL) may be disposed on the second bank (BNK2), the reflective layer (RFL), the first and second light conversion patterns (CCP1, CCP2), and the light scattering pattern (LSP). The low refractive layer (LRL) may have a refractive index lower than a refractive index of the first and second light conversion patterns (CCP1, CCP2) and the light scattering patterns (LSP). The low refractive layer (LRL) may be configured to refract or total reflect the light depending on the angle of incidence of light. The low refractive layer (LRL) may provide light that has passed through the first and second light conversion patterns (CCP1, CCP2) and the light scattering pattern (LSP) back to the first and second light conversion patterns (CCP1, CCP2) and the light scattering pattern (LSP). Accordingly, the light conversion efficiency and light scattering efficiency of first and second light conversion patterns (CCP1, CCP2) and the light scattering pattern (LSP) may be improved. In embodiments, the low refractive layer (LRL) in the third subpixel (SP3) may be omitted.

The color filter layer (CFL) may be disposed on the low refractive layer (LRL). The color filter layer (CFL) may include first to third color filters (CF1, CF2, CF3) and light blocking patterns (LBP).

The first to third color filters (CF1, CF2, CF3) may overlap the first and second light conversion patterns (CCP1, CCP2) and the light scattering pattern (LSP) in the third direction DR3, respectively. Each of the first to third color filters (CF1, CF2, CF3) may selectively transmit light in the desired wavelength range. If the first subpixel (SP1) is a red subpixel, the first color filter (CF1) may include a red color filter. If the second subpixel (SP2) is a green subpixel, the second color filter (CF2) may include a green color filter. If the third subpixel (SP3) is a blue subpixel, the third color filter (CF3) may include a blue color filter. The first to third color filters (CF1, CF2, CF3) may have a refractive index higher than the refractive index of the low refractive layer (LRL). However, the embodiments are not limited thereto, and the first to third color filters (CF1, CF2, CF3) may have a refractive index lower than or equal to the refractive index of the low refractive layer (LRL).

The light blocking patterns (LBP) may be disposed between the first to third color filters (CF1, CF2, CF3). that the light blocking patterns (LBP) may define the light emitting area (or a light releasing area) (EMA) and non-light emitting area (NEMA) for the first to third subpixels (SP1, SP2, SP3). An area that overlaps the light blocking patterns (LBP) in the third direction DR3 may correspond to the non-light emitting area (NEMA). An area that does not overlap the light blocking patterns (LBP) in the third direction DR3 may correspond to the light emitting area (EMA).

In embodiments, the light blocking patterns (LBP) may include a light blocking material. In embodiments, each of the light blocking patterns (LBP) may be provided in the form of multi-layers in which at least two color filters of the first to third color filters (CF1, CF2, CF3) overlap each other in the third direction DR3. For example, each of the light blocking patterns (LBP) may be formed by overlapping the first to third color filters (CF1, CF2, CF3) in the third direction DR3. In another embodiment, the light blocking pattern (LBP) between the first and second color filters (CF1, CF2) among the light blocking patterns (LBP) may be formed as multi-layers in which the first and second color filters (CF1, CF2) overlap, and the light blocking pattern (LBP) between the second and third color filters (CF2, CF3) among the light blocking patterns (LBP) may be formed as multi-layers in which the second and third color filters (CF2, CF3) overlap in the third direction DR3. The light blocking pattern (LBP) between the first color filter (CF1) and the third color filter (CF3) of neighboring pixels may be formed as multi-layers in which the first and third color filters (CF1, CF3) overlap each other in the third direction DR3. As such, each of the first to third color filters (CF1, CF2, CF3) may extend to the non-light emitting area (NEMA) to form light blocking patterns (LBP).

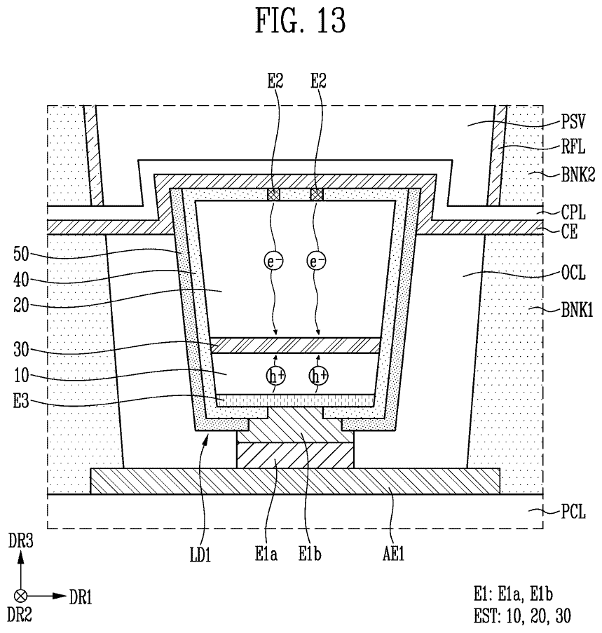

FIG. 13 is a schematic enlarged cross-sectional view of some of areas of FIG. 12. Hereinafter, description will be set forth on the first light emitting element (LD1), which is configured to be substantially identical to the light emitting element (LD) described in reference to FIG. 6 to FIG. 9. Since the second and third emitting elements (LD2, LD3) may also be configured to be substantially identical to the light emitting element (LD) described in reference to FIG. 6 to FIG. 9, the description hereinafter may be applied to be substantially identical (or similar) to the second and third light emitting element (LD2, LD3).

Referring to FIG. 13, the first light emitting element (LD1) may be interposed between the first anode electrode (AE1) and the cathode electrode (CE) facing the first anode electrode (AE1).

The first electrode (E1) of the first light emitting element (LD1) may be electrically connected to the first anode electrode (AE1). For example, as the bonding electrode (E1a) of the first light emitting element (LD1) is bonded and coupled to the first anode electrode (AE1), the first electrode (E1) and the first anode electrode (AE1) may be electrically connected to each other.

The second electrode (E2) of the first light emitting element (LD1) may be electrically connected to the cathode electrode (CE). For example, the cathode electrode (CE) may electrically contact the upper surface of the second electrode (E2) that is exposed without being covered by the first insulation film 40.

The electrical signal provided by the cathode electrode (CE) may be transmitted to the second semiconductor layer 20 through the second electrode (E2). Based on this, the moving path of electrons (e-) may be formed in a direction from the second electrode (E2) to the active layer 30 in the second semiconductor layer 20. Similarly, the electrical signal provided by the first anode electrode (AE1) may be transmitted to the first semiconductor layer 10 through the first electrode (E1). Based on this, the moving path of holes (h+) may be formed in a direction from the contact surface of the first electrode (E1) that is in electrical contact with the auxiliary electrode (E3) in the first opening (OP_40, see FIG. 9) in the first semiconductor layer 10 toward the active layer 30.

As the first light emitting element (LD1) is configured to be substantially identical to the light emitting element (LD) described in reference to FIG. 6 to FIG. 9, the moving path of electrons in the second semiconductor layer 20 and the moving path of holes in the first semiconductor layer 10 may be more centralized. Accordingly, electrons and holes may be provided more efficiently to the active layer 30, such that the luminous efficiency of the first light emitting element (LD1) may be improved.

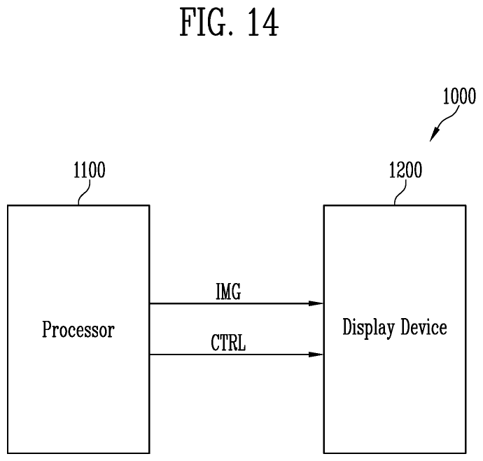

FIG. 14 is a schematic block diagram for illustrating a display system according to one embodiment.

Referring to FIG. 14, a display system 1000 may include a processor 1100 and a display device 1200.

The processor 1100 may perform a variety of tasks and calculations. In embodiments, the processor 1100 may include an application processor, a graphics processor, a microprocessor, and a central processing unit (CPU). The processor 1100 may be connected to other components of the display system 1000 through a bus system to control the components.

The processor 1100 may transmit image data (IMG) and control signals (CTRL) to the display device 1200. The display device 1200 may display images based on the image data (IMG) and the control signal (CTRL). The display device 1200 may be configured as the display device (DD) described in reference to FIG. 1. The image data (IMG) and the control signal (CTRL) may be provided as input image data (IMG) and control signals (CTRL) of FIG. 1, respectively.

The display system 1000 may include a computing system that provides image display functions and may be applied to a smart watch, mobile phone, smart phone, portable computer, tablet personal computer (PC), watch phone, automotive display, smart glasses, portable multimedia player (PMP), navigator, or ultra mobile personal computer (UMPC). In another embodiment, the display system 1000 may be applied to a head mounted display (HMD), a virtual reality (VR) device, a mixed reality (MR) device, or an augmented reality (AR) device.

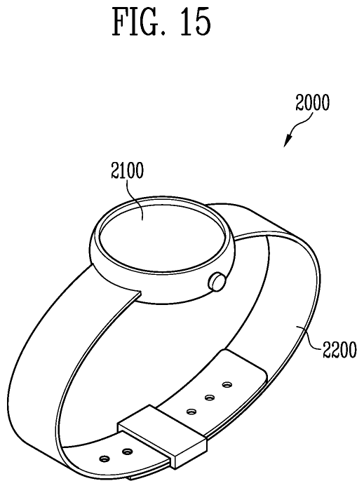

FIG. 15 to FIG. 18 are perspective views for illustrating embodiments of the display system of FIG. 14.

Referring to FIG. 15, the display system 1000 of FIG. 14 may be applied to a smart watch 2000 including a display unit 2100 and a strap unit 2200.

The smart watch 2000 may be a wearable electronic device. For example, the smart watch 2000 may have a structure in which the strap unit 2200 may be mounted on the user's wrist. The display unit 2100 may be applied with the display system 1000 and/or the display device 1200 so that image data including time information may be provided to a user.

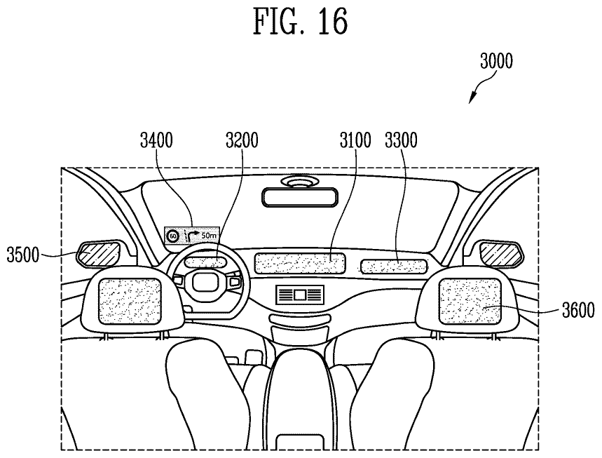

Referring to FIG. 16, the display system 1000 of FIG. 14 may be applied to an automotive display system 3000. The automotive display system 3000 may include a computing system that is equipped inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600 that are provided inside the vehicle.

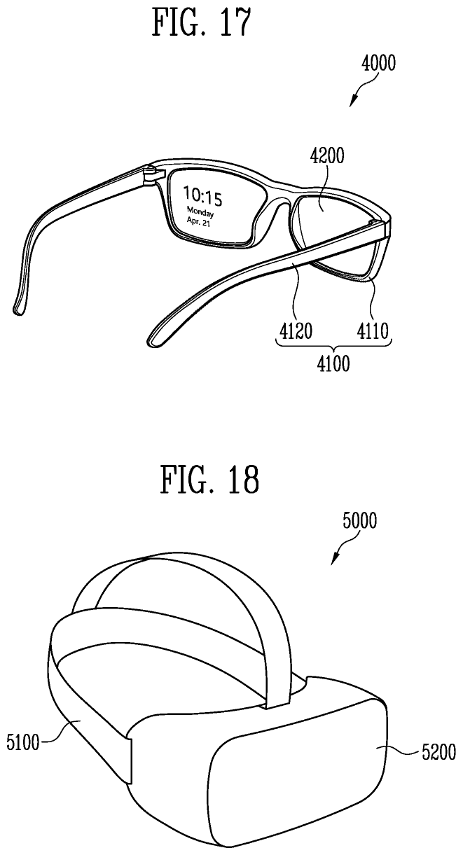

Referring to FIG. 17, the display system 1000 of FIG. 14 may be applied to a smart glasses 4000. The smart glasses 4000 may be a wearable electronic device that are wearable on the user's head. For example, the smart glasses 4000 may be a wearable device for augmented reality.

The smart glass 4000 may include a frame 4100 and a lens unit 4200. The frame 4100 may include a housing 4110 supporting the lens unit 4200 and a leg unit 4120 that may be mounted on the user. The leg unit 4120 may be connected to the housing 4110 by a hinge to be folded or unfolded with respect to the housing 4110.

The frame 4100 may be built in with a battery, touchpad, microphone, and camera. In another embodiment, the frame 4100 may be built in with a projector to output light and a processor to control the light signal.

The lens unit 4200 may include an optical member that transmits or reflects light. For example, the lens unit 4200 may include glass or a transparent synthetic resin.

In order for the user's eyes to perceive the visual information, the lens unit 4200 may reflect the image by the light signal emitted from the projector of the frame 4100 on the rear surface of the lens unit 4200 (e.g., a surface facing the user's eyes). For example, the user may recognize visual information such as time and date displayed on the lens unit 4200. The projector and/or the lens unit 4200 may be a type of display device. The display device 1200 may be applied to the projector and/or the lens unit 4200.

Referring to FIG. 18, the display system 1000 of FIG. 14 may be applied to a head-mounted display device 5000.

The head-mounted display device 5000 may be a wearable electronic device that is wearable on the user's head. For example, the head-mounted display device 5000 may be a wearable device for virtual reality or mixed reality.

The head-mounted display device 5000 may include a head-mounted band 5100 and a display device storage case 5200. The head-mounted band 5100 may be connected to the display device storage case 5200. The head-mounted band 5100 may include a horizontal band and/or a vertical band for fixing the head-mounted display device 5000 to the user's head. The horizontal band may be configured to surround the side of the user's head, and the vertical band may be configured to surround the upper part of the user's head. However, embodiments are not limited thereto. For example, the head-mounted band 5100 may be implemented in the form of glass frames and helmets.

The display device storage case 5200 may store the display system 1000 and/or the display device 1200.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting element, comprising:
a light emitting stack comprising a first semiconductor layer, a second semiconductor layer disposed on the first semiconductor layer, and an active layer interposed between the first semiconductor layer and the second semiconductor layer;
an auxiliary electrode covering a lower surface of the light emitting stack;
a first insulation film covering an outer peripheral surface of the light emitting stack and the auxiliary electrode and comprising a first opening exposing a portion of a lower surface of the auxiliary electrode;
a second insulation film covering an outer peripheral surface of the first insulation film, exposing an upper surface of the first insulation film, and comprising a second opening exposing the first opening and a portion of the first insulation film adjacent to the first opening;
a first electrode electrically contacting the portion of the lower surface of the auxiliary electrode that is exposed by the first and second openings; and
a second electrode embedded in the first insulation film and electrically contacting an upper surface of the light emitting stack,
wherein the second electrode has a line or dotted line forming a closed-loop shape in a plan view.

2. The light emitting element of claim 1, wherein, in a cross-sectional view, an upper surface of the second electrode and the upper surface of the first insulation film are positioned at a same height.

3. The light emitting element of claim 1, wherein an area of the second opening is greater than an area of the first opening in a plan view.

4. The light emitting element of claim 3, wherein the area of the second opening is less than or equal to about 30% of an area of the lower surface of the light emitting stack in a plan view.

5. The light emitting element of claim 1, wherein, in a plan view, the second electrode overlaps an edge of the first opening.

6. The light emitting element of claim 1, wherein the first electrode comprises:
a reflective electrode electrically contacting the portion of the lower surface of the auxiliary electrode; and
a bonding electrode disposed below the reflective electrode.

7. The light emitting element of claim 1, wherein a center of the closed-loop shape of the second electrode overlaps a center of the upper surface of the light emitting stack in a plan view.

8. The light emitting element of claim 1, wherein the second insulation film has a laminated structure of:
a first insulation layer having a first refractive index; and
a second insulation layer having a second refractive index that is different from the first refractive index.

9. The light emitting element of claim 1, wherein the second electrode comprises a conductive metal oxide.

10. The light emitting element of claim 1, wherein, in a cross-sectional view, the light emitting stack has a trapezoidal shape in which a length of the upper surface is greater than a length of the lower surface.

11. A display device comprising:
an anode electrode;
a cathode electrode facing the anode electrode; and
a light emitting element interposed between the anode electrode and the cathode electrode, wherein
the light emitting element comprises:
a light emitting stack comprising a first semiconductor layer, a second semiconductor layer disposed on the first semiconductor layer, and an active layer interposed between the first semiconductor layer and the second semiconductor layer;
an auxiliary electrode covering a lower surface of the light emitting stack;
a first insulation film covering an outer peripheral surface of the light emitting stack and the auxiliary electrode and comprising a first opening exposing a portion of a lower surface of the auxiliary electrode;
a second insulation film covering an outer peripheral surface of the first insulation film, exposing an upper surface of the first insulation film, and comprising a second opening exposing the first opening and a portion of the first insulation film adjacent to the first opening;
a first electrode electrically contacting the portion of the lower surface of the auxiliary electrode that is exposed by the first and second openings and electrically connected to the anode electrode; and
a second electrode embedded in the first insulation film, electrically contacting an upper surface of the light emitting stack, and electrically connected to the cathode electrode, and
the second electrode has a line or dotted line forming a closed-loop shape in a plan view.

12. The display device of claim 11, wherein,
in a cross-sectional view, an upper surface of the second electrode and the upper surface of the first insulation film are positioned at a same height as, and
the cathode electrode electrically contacts the upper surface of the second electrode.

13. The display device of claim 11, wherein
an area of the second opening is greater than an area of the first opening in a plan view, and
the area of the second opening is less than or equal to about 30% of an area of the lower surface of the light emitting stack in a plan view.

14. The display device of claim 11, wherein, in a plan view, the second electrode overlaps an edge of the first opening.

15. The display device of claim 11, wherein the first electrode comprises:
a reflective electrode electrically contacting the portion of the lower surface of the auxiliary electrode; and
a bonding electrode disposed below the reflective electrode and bonded to the anode electrode.

16. The display device of claim 11, wherein a center of the closed-loop shape of the second electrode overlaps a center of the upper surface of the light emitting stack in a plan view.

17. The display device of claim 11, wherein the second insulation film has a laminated structure of:
a first insulation layer having a first refractive index; and
a second insulation layer having a second refractive index that is different from the first refractive index.

18. The display device of claim 11, wherein the second electrode comprises a conductive metal oxide.

19. The display device of claim 11, wherein, in a cross-sectional view, the light emitting stack has a trapezoidal shape in which a length of the upper surface is greater than a length of the lower surface.

20. An electronic device, comprising:
a processor that provides image data; and
a display device that displays an image based on the image data, wherein
the display device comprises an anode electrode, a cathode electrode facing the anode electrode, and a light emitting element interposed between the anode electrode and the cathode electrode,
the light emitting element comprises:
a light emitting stack comprising a first semiconductor layer, a second semiconductor layer disposed on the first semiconductor layer, and an active layer interposed between the first semiconductor layer and the second semiconductor layer;
an auxiliary electrode covering a lower surface of the light emitting stack;
a first insulation film covering an outer peripheral surface of the light emitting stack and the auxiliary electrode and comprising a first opening exposing a portion of a lower surface of the auxiliary electrode;
a second insulation film covering an outer peripheral surface of the first insulation film, exposing an upper surface of the first insulation film, and comprising a second opening exposing the first opening and a portion of the first insulation film adjacent to the first opening;
a first electrode electrically contacting the portion of the lower surface of the auxiliary electrode that is exposed by the first and second openings and electrically connected to the anode electrode; and
a second electrode embedded in the first insulation film, electrically contacting an upper surface of the light emitting stack, and electrically connected to the cathode electrode, and
the second electrode has a line or dotted line forming a closed-loop shape in a plan view.
